(19) United States
(12) Patent Application Publication
(10) Pub. No.: US 2016/0013031 A1
(43) Pub. Date: Jan. 14, 2016

(54) Substrate Processing Device and Method of Handling Particles Thereof

(71) Applicant: PSK Inc., Gyeonggi-do (KR)

(72) Inventors: Hee Sun Chae, Gyeonggi-do (KR); Jeong Hee Cho, Gyeonggi-do (KR); Jong Sik Lee, Gyeonggi-do (KR); Han Saem Lee, Gyeonggi-do (KR); Hyun Jun Kim, Gyeonggi-do (KR)

(21) Appl. No.: 14/459,222

(22) Filed: Aug. 13, 2014

(30) Foreign Application Priority Data
Jul. 8, 2014 (KR) 10-2014-0085212

(51) Int. Cl. H01J 37/32; B08B 7/00

(52) U.S. Cl. CPC H01J 37/32871; H01J 37/32082; H01J 37/32633; B08B 7/0035

(57) ABSTRACT

Provided are a substrate processing device and a method of handing particles thereof. The substrate processing device includes: a process chamber providing a space in which a substrate is processed; a substrate support unit arranged in the process chamber and supporting the substrate; a plasma chamber providing a space in which plasma is generated; a gas supply unit supplying a process gas to the plasma chamber; a plasma source installed in the plasma chamber, wherein the plasma source generates the plasma from the process gas; a radio frequency (RF) power supply providing the plasma source with an RF signal for generating the plasma; a baffle arranged on the substrate support unit, wherein the baffle evenly supplies the plasma to a processing space in the process chamber; a direct current (DC) power supply applying a DC voltage to the baffle; a discharge unit discharging a particle generated in the process chamber by substrate processing; and a control unit controlling the DC power supply and handing the particle to prevent the contamination of the substrate by the particle.

### CROSS-REFERENCE TO RELATED APPLICATIONS

This U.S. non-provisional patent application claims priority under 35 U.S.C. §119 of Korean Patent Application No. 10-2014-0085212, filed on Jul. 8, 2014, the entire contents of which are hereby incorporated by reference.

### BACKGROUND OF THE INVENTION

The present invention disclosed herein relates to a substrate processing device and a method of handling particles thereof.

Recently, a cleaning or etching process of substrate processing processes has mainly used a dry process rather than a wet process using chemicals. Among others, dry cleaning and dry etching have been widely used which remove a thin film from a substrate by using plasma.

A particle that is generated by a reaction between a gas and the thin film during such a dry process is consistently deposited throughout a chamber and thus interferes with the process. Furthermore, when such a particle falls onto the substrate, a corresponding part may have a defect.

When the particle is generated in the substrate processing process using plasma, the particle is charged by the plasma and clings to a surface of a chamber by electric force or floats in the plasma. Then, when the process ends and the generation of the plasma stops, pumping is performed so that the particles in the chamber are discharged through a pump line, but there is a limitation in that some of the particles in this process remain on the substrate and thus contaminates the substrate.

### SUMMARY OF THE INVENTION

The present invention provides a substrate processing device that handles particles in a substrate processing process to prevent the particles from remaining on a substrate, and a method of handling particles thereof.

The present invention also provides a substrate processing device that includes a particle handling process during a substrate processing process that does not affect the generation of plasma, and a method of handling particles thereof.

The present invention also provides a substrate processing device that effectively discharges particles piled up in a chamber to the outside of the chamber during a process, and a method of handing particles thereof.

Embodiments of the present invention provide substrate processing devices including: a process chamber providing a space in which a substrate is processed; a substrate support unit arranged in the process chamber and supporting the substrate; a plasma chamber providing a space in which plasma is generated; a gas supply unit supplying a process gas to the plasma chamber; a plasma source installed in the plasma chamber and generating the plasma from the process gas; a radio frequency (RF) power supply providing the plasma source with an RF signal for generating the plasma; a baffle arranged over the substrate support unit and evenly supplying the plasma to a processing space in the process chamber; a direct current (DC) power supply applying a DC voltage to the baffle; a discharge unit discharging a particle generated in the process chamber during substrate processing; and a control unit controlling the DC power supply and handing the particle to prevent the contamination of the substrate by the particle.

In some embodiments, the DC power supply may supply a negative DC voltage to the baffle.

In other embodiments, the control unit may enable the DC power supply to apply the negative DC voltage to the baffle after substrate processing ends.

In still other embodiments, the control unit may enable the DC power supply to initiate the application of the negative DC voltage when the RF power supply ends the output of an RF signal.

In even other embodiments, the control unit may enable the DC power supply to end the application of the negative DC voltage when the substrate is discharged from the process chamber.

In yet other embodiments, the DC power supply may apply a positive DC voltage to the baffle.

In further embodiments, the control unit may enable the DC power supply to apply the positive DC voltage to the baffle during substrate processing.

In still further embodiments, the control unit may enable the DC power supply to initiate the application of the positive DC voltage when the RF power supply initiates the output of an RF signal.

In even further embodiments, the control unit may enable the DC power supply to end the application of the positive DC voltage when the substrate is discharged from the process chamber.

In yet further embodiments, after the application of the positive DC voltage ends, the control unit may enable the DC power supply to further apply a positive DC voltage to the baffle for a preset time.

In much further embodiments, the substrate processing devices may further include an intake duct arranged between the plasma chamber and the process chamber and connecting a plasma generation space to a substrate processing space, wherein the baffle is coupled to an end of the intake duct adjacent to the process chamber.

In other embodiments of the present invention, methods of handling by a substrate processing device a particle generated during substrate processing include injecting by a gas supply unit a process gas to a plasma chamber; providing by an RF power supply a plasma source with an RF signal to process a substrate; and applying by a DC power supply a DC voltage to a baffle to prevent the substrate from becoming contaminated by the particle.

In some embodiments, the applying of the DC voltage may include applying by the DC power supply a negative DC voltage to the baffle.

In other embodiments, the applying of the negative DC voltage may include applying by the DC power supply a negative DC voltage to the baffle after substrate processing ends.

In still other embodiments, the applying of the negative DC voltage to the baffle after the substrate processing ends may include initiating the application of a negative DC voltage by the DC power supply when the RF power supply ends the output of an RF signal.

In even other embodiments, the applying of the negative DC voltage to the baffle after the substrate processing ends may include ending the application of a negative DC voltage by the DC power supply when the substrate is discharged from a process chamber.

In yet other embodiments, the applying of the DC voltage may include applying by the DC power supply a positive DC voltage to the baffle.

In further embodiments, the applying of the positive DC voltage may include applying by the DC power supply a positive DC voltage to the baffle during substrate processing.

In still further embodiments, the applying of the positive DC voltage to the baffle during the substrate processing may include initiating by the DC power supply the application of a positive DC voltage when the RF power supply initiates the output of an RF signal.

In even further embodiments, the applying of the positive DC voltage to the baffle during the substrate processing may include ending the application of a positive DC voltage by the DC power supply when the substrate is discharged from a process chamber.

In yet further embodiments, the methods may further include, after the application of the positive DC voltage ends, applying by the DC power supply to apply a positive DC voltage to the baffle for a preset time.

In still other embodiments of the present invention, the methods according to embodiments of the present invention are implemented as a program that may be executed by a computer, and are recorded in a computer readable recording medium.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is an exemplary diagram of a substrate processing device according to an embodiment of the present invention;

FIG. 2 is an exemplary diagram for explaining orders in which a radio frequency (RF) power supply and a direct current (DC) power supply are controlled to handle a particle according to an embodiment of the present invention;

FIG. 3 is an exemplary diagram representing the behavior of a particle according to an embodiment of the present invention;

FIG. 4 is an exemplary diagram for explaining orders in which an RF power supply and a DC power supply are controlled to handle a particle according to another embodiment of the present invention;

FIG. 5 is an exemplary diagram representing the behavior of a particle according to another embodiment of the present invention;

FIG. 6 is an exemplary diagram representing the behavior of a particle according to still another embodiment of the present invention;

FIG. 7 is an exemplary flow chart of a method of handing a particle according to an embodiment of the present invention;

FIG. 8 is an exemplary flow chart of a DC voltage application process according to an embodiment of the present invention; and

FIG. 9 is an exemplary flow chart of a DC voltage application process according to another embodiment of the present invention.

### DETAILED DESCRIPTION OF PREFERRED EMBODIMENTS

Other advantages and features of the present invention, and implementation methods thereof will be clarified through following embodiments to be described in detail with reference to the accompanying drawings. The present invention may, however, be embodied in different forms and should not be construed as limited to the embodiments set forth herein. Rather, these embodiments are provided so that this disclosure is thorough and complete and fully conveys the scope of the present invention to a person skilled in the art. Further, the present invention is only defined by scopes of claims.

Even if not defined, all the terms used herein (including technology or science terms) have the same meanings as those generally accepted by typical technologies in the related art to which the present invention pertains. The terms defined in general dictionaries may be construed as having the same meanings as those used in the related art and/or the present disclosure and even when some terms are not clearly defined, they should not be construed as being conceptual or excessively formal.

The terms used herein are only for explaining embodiments and not intended to limit the present invention. The terms of a singular form in the disclosure may also include plural forms unless otherwise specified. The terms used herein “includes”, “comprises”, “including” and/or “comprising” do not exclude the presence or addition of one or more compositions, ingredients, components, steps, operations and/or elements other than the compositions, ingredients, components, steps, operations and/or elements that are mentioned. In the present disclosure, the term “and/or” indicates each of enumerated components or various combinations thereof.

Various embodiments of the present invention are described below in detail with reference to the accompanying drawings.

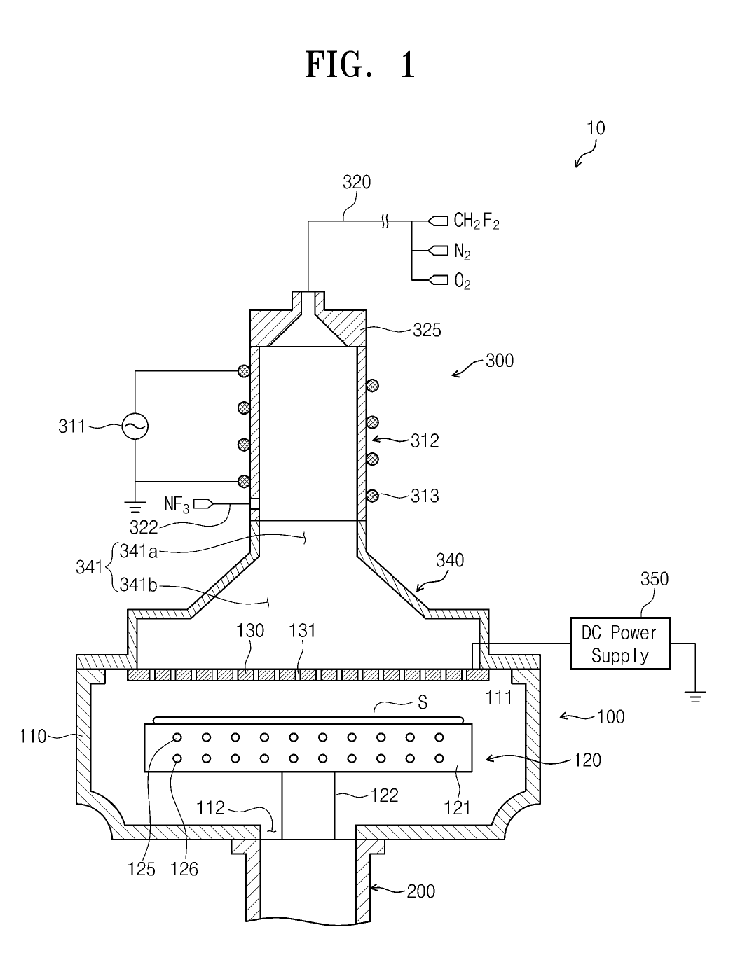

FIG. 1 is an exemplary diagram of a substrate processing device 10 according to an embodiment of the present invention.

Referring to FIG. 1, the substrate processing device 10 may process, such as clean, etch or ash a thin film on a substrate S by using plasma. The thin film to be processed may be a nitride film, which may be a silicon nitride film but the type of the thin film to be processed is not limited thereto.

The substrate processing device 10 may have a process unit 100, a discharge unit 200, and a plasma generation unit 300. The process unit 100 may provide a space on which the substrate is placed and processes are performed. The discharge unit 200 may externally discharge a process gas staying in the process unit 100 and the by-products of a reaction generated in a substrate processing process, and maintain the pressure in the process unit 100 at a set pressure. The plasma generation unit 300 may generate plasma from a process gas externally supplied and supply the plasma to the process unit 100.

The process unit 100 may include a process chamber 110, a substrate support unit 120, and a baffle 130. A processing space 111 in which the substrate processing process is performed may be formed in the process chamber 110. The upper wall of the process chamber 110 may be open and a sidewall thereof may have an opening (not shown). A substrate may enter and exit the process chamber 110 through the opening. The opening may be opened or closed by an opening/closing member such as a door (not shown). A discharge hole 112 may be formed at the bottom of the process chamber 110. The discharge hole 112 may be connected to the discharge unit 200 and provide a path through which gases staying in the process chamber 110 and the by-products of a reaction are externally discharged.

The substrate support unit 120 may support the substrate S. The substrate support unit 120 may include a susceptor 121 and a support shaft 122. The susceptor 121 may be placed in the processing space 111 and provided in a disc shape. The susceptor 121 may be supported by the support shaft 122. The substrate S may be placed on the top of the susceptor 121. An electrode (not shown) may be provided in the susceptor 121. The electrode may be connected to an external power supply and generate static electricity by applied power. Generated static electricity may fix the substrate S to the susceptor 121. A heating member 125 may be provided in the susceptor 121. According to an example, the heating member 125 may be a heating coil. Also, a cooling member 126 may be provided in the susceptor 121. The cooling member may be provided as a cooling line through which cooling water flows. The heating member 125 may heat the substrate S to a preset temperature. The cooling member 126 may forcibly cool the substrate S. The substrate S on which processing is completed may be cooled to room temperature or a temperature needed for the next process.

The baffle 130 may be placed over the susceptor 121. Holes 131 may be formed in the baffle 130. The holes 130 may be provided as through holes that are provided from the top of the baffle 130 to the bottom thereof, and may be evenly formed throughout the baffle 130.

Referring back to FIG. 1, the plasma generation unit 300 may be arranged over the process chamber 110. The plasma generation unit 300 may discharge a process gas to generate plasma, and supply generated plasma to the processing space 111. The plasma generation unit 300 may include a first radio frequency (RF) 311, a plasma chamber 312 and a coil 313. Furthermore, the plasma generation unit 300 may further include a first source gas supply unit 320, a second source gas supply unit 322 and an intake duct 340.

The plasma chamber 312 may be arranged external to the process chamber 110. According to an embodiment, the plasma chamber 312 may be arranged over the process chamber 110 and coupled thereto. The plasma chamber 312 may include a discharge space 311 of which the top and the bottom are opened. The upper end of the plasma chamber 312 may be airtight by a gas supply port 325. The gas supply port 325 may be connected to the first source gas supply unit 320. A first source gas may be supplied to the discharge space 311 through the gas supply port 325. The first source gas may include difluoromethane (CH₂F₂), nitrogen (N₂), and oxygen (O₂). Selectively, the first source gas may further include another kind of gas such as tetrafluoromethane (CF₄).

The coil 313 may be an inductively coupled plasma (ICP) coil. The coil 313 may be wound several times on the plasma chamber 312 outside the plasma chamber 312. The coil 313 may be wound on the plasma chamber 312 on a region corresponding to the discharge space 311. One end of the coil 313 may be connected to an RF power supply 311 and the other end thereof may be earthed.

The RF power supply 311 may supply high-frequency power to the coil 313. The high-frequency power supplied to the coil 313 may be applied to the discharge space 311. An induced electric field may be formed in the discharge space 311 by the high-frequency power and a first process gas in the discharge space 311 may obtain energy needed for ionization from the induced electric field to be converted into a plasma state.

Although an ICP source using the coil 313 is described above, the plasma source is not limited thereto and may also be configured as a CCP type that uses facing electrodes.

The intake duct 340 may be arranged between the plasma chamber 312 and the process chamber 110. The intake duct 340 may enable the opened top of the process chamber 130 to be airtight and the baffle 130 may be coupled to the lower end of the intake duct 340. An intake space 341 may be formed in the intake duct 340. The intake space 341 may be provided as a path that connects the discharge space 311 to the processing space 111 and supplies the plasma generated in the discharge space 311 to the processing space 111.

The intake space 341 may include an intake hole 341a and a diffusion space 341b. The intake hole 341a may be formed under the discharge space 311 and connected thereto. Plasma generated in the discharge space 311 may flow into the intake hole 341a. The diffusion space 341b may be arranged under the intake hole 341a and connect the intake hole 341a to he processing space 111. The diffusion space 341b may have a cross section that gradually widens progressively downward. The diffusion space 341b may have an inverted funnel shape. Plasma supplied from the intake hole 341a may be diffused while passing through the diffusion space 341b.

The second source gas supply unit 322 may be connected to a path through which plasma generated in the discharge space 311 is supplied to the process chamber 110. For example, the second source gas supply unit 322 may supply a second source to a path through which plasma flows, between where the lower end of the coil 313 is arranged and where the upper end of the diffusion space 341b is arranged. According to an example, the second source gas may include nitrogen trifluoride NF₃. Selectively, processes may also be performed only by the first source gas without the supply of the second source gas.

According to an embodiment of the present invention, the substrate processing device 10 further includes a DC power supply 350, and a control unit (not shown) that controls the DC power supply. The DC power supply 350 applies a DC voltage to the baffle 130. The control unit controls the DC power supply 350 so that a particle generated in a chamber by substrate processing does not contaminate the substrate S.

As such, when the DC power supply 350 applies the DC voltage to the baffle 130, the baffle 130 is coupled to the lower end of the intake duct 340 through an insulator (not shown).

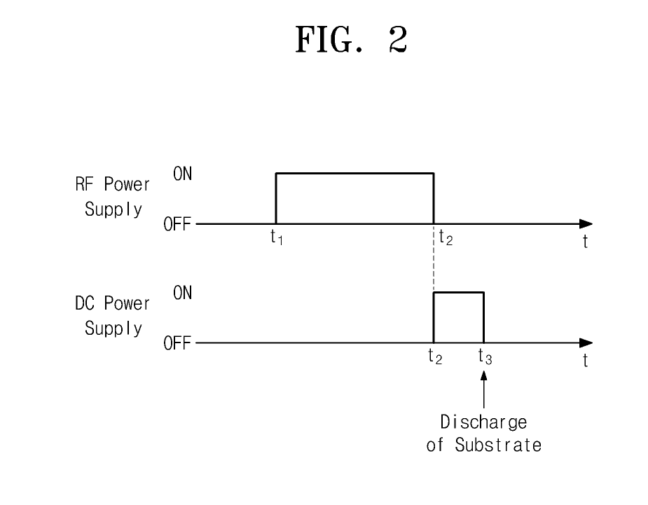

FIG. 2 is an exemplary diagram for explaining orders in which the RF power supply 311 and the DC power supply 350 are controlled to handle a particle according to an embodiment of the present invention.

According to an embodiment of the present invention, the DC power supply 350 may apply a negative DC voltage to the baffle 130. In this case, the control unit may enable the DC power supply 350 to apply a negative DC voltage to the baffle 130 after substrate processing ends.

For example, referring to FIG. 2, the RF power supply 311 may start outputting an RF signal at time t₁ and provide a plasma source (such as a coil 313 in FIG. 1) with the RF signal so that plasma is generated in the plasma chamber 312 and substrate processing is performed. The substrate processing process may be performed for a preset time and the RF power supply 311 may end the output of the RF signal at time t₂ so that the substrate processing process ends.

Then, when the RF power supply 311 ends the output the RF signal, the control unit may enable the DC power supply 350 to apply a negative DC voltage to the baffle 130 at time t₂. The application of the negative DC voltage to the baffle 130 may last until the substrate S is discharged from the process chamber 110. That is, the control unit may enable the DC power supply 350 to end the application of the negative DC voltage at time t₃ when the substrate S is discharged from the process chamber 110.

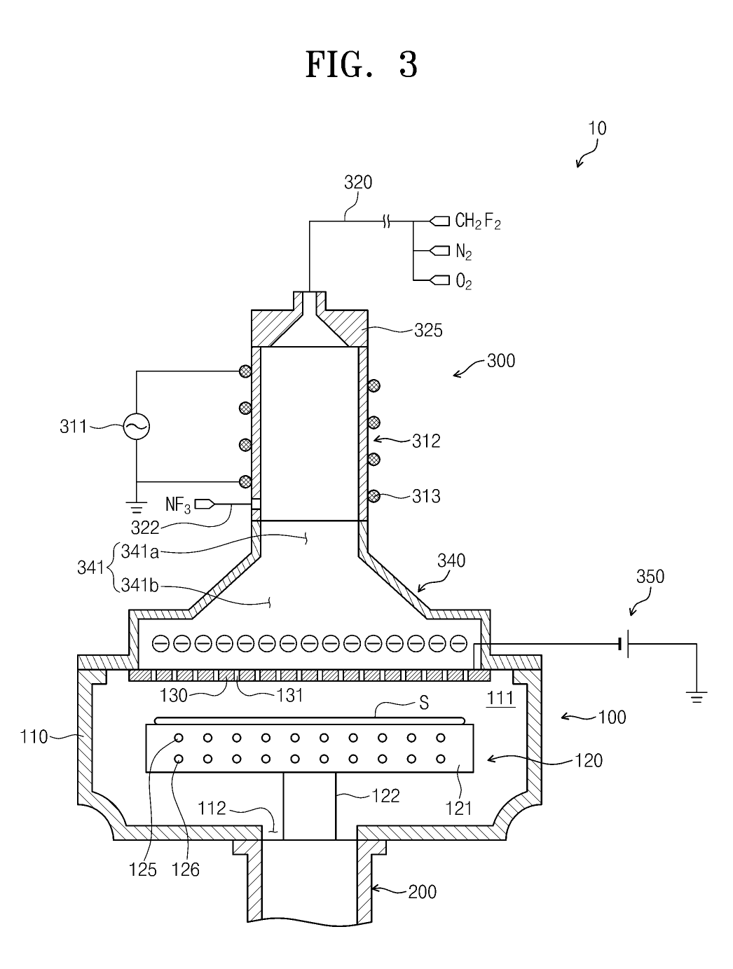

FIG. 3 is an exemplary diagram representing the behavior of a particle according to an embodiment of the present invention.

As described with reference to FIG. 2, when a negative DC power is applied to the baffle 130 after substrate processing ends, a particle that is negatively charged and floats in a chamber may float at a certain distance from the baffle 130 by the baffle 130 negatively-charged even after a process ends.

That is, the baffle 130 that receives the negative DC voltage and thus is negatively charged applies a repulsive force to the negatively-charged particle so that the particle floats on the baffle 130. As a result, since the particle does not fall onto the substrate S even after a process ends, it is possible to prevent the substrate from becoming contaminated.

Then, when the substrate S is discharged from the process chamber 110, the baffle 130 no longer receives the negative DC voltage. Thus, a particle floating on the baffle 130 falls and is discharged to the outside of the chamber by the discharge unit 200.

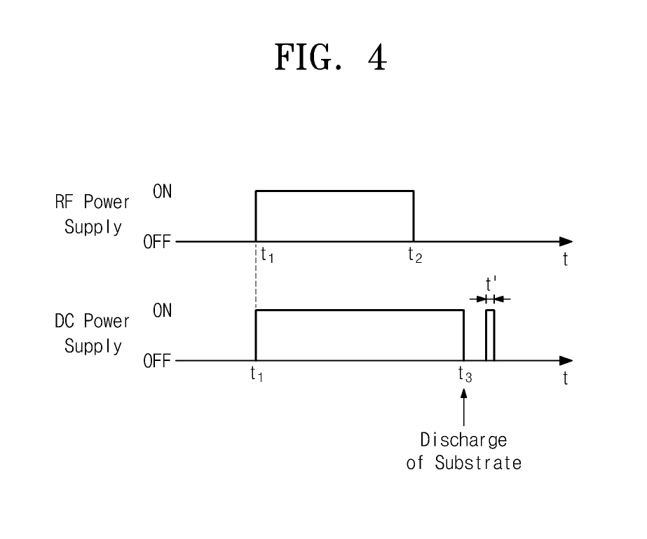

FIG. 4 is an exemplary diagram for explaining orders in which the RF power supply 311 and the DC power supply 350 are controlled to handle a particle according to another embodiment of the present invention.

According to another embodiment of the present invention, the DC power supply 350 may apply a positive DC voltage to the baffle 130, unlike the above-described embodiments. In this case, the control unit may enable the DC power supply 350 to apply a positive DC voltage to the baffle 130 while substrate processing is performed.

Referring to FIG. 4, when the RF power supply 311 outputs an RF signal at time t₁ and plasma is generated in the plasma chamber 312, the DC power supply 350 may also apply the negative DC voltage to the baffle 130 at time t₁.

According to the present embodiment, the application of the positive DC voltage to the baffle 130 lasts even after time t₂ when the RF power supply 311 ends the output of the RF signal. Then, the DC power supply 350 may end the application of the positive DC voltage to the baffle 130 at time t₃ when the substrate S is discharged from the process chamber 110.

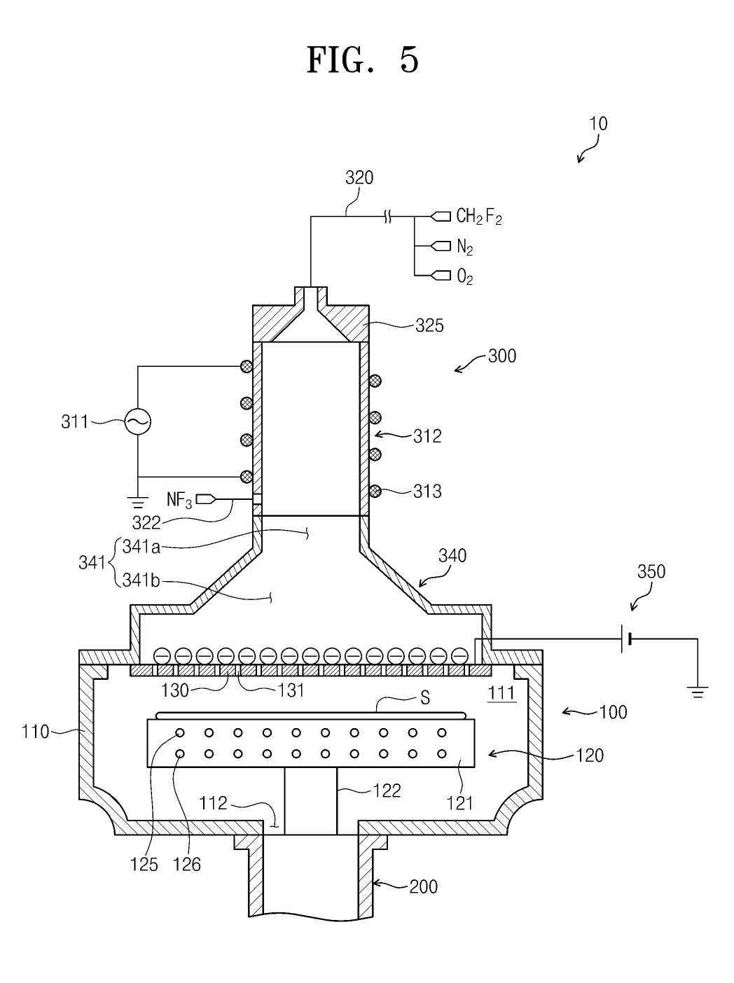

FIG. 5 is an exemplary diagram representing the behavior of a particle according to another embodiment of the present invention.

As described with reference to FIG. 4, when a positive DC voltage is applied to the baffle 130 while substrate processing is performed, a negatively-charged particle is attached to a positively-charged baffle 130. That is, an attractive force works between the baffle 130 positively-charged by the application of the positive DC voltage and the negatively-charged particle, so the particle may be attached to the baffle 130. As a result, since a particle generated during a process clings to the baffle 130 in a chamber and thus does not fall onto a substrate until the substrate S is discharged from the chamber, it is possible to prevent the substrate from becoming contaminated.

Then, when the substrate S is discharged from the process chamber 110, the positive DC voltage that has been applied to the baffle 130 has been interrupted. Thus, the particle attached to the baffle 130 is discharged to the outside of the chamber by the discharge unit 200.

According to still another embodiment of the present invention, after the application of the positive DC voltage ends, the control unit may enable the DC power supply 350 to further apply a positive DC voltage to the baffle 130 for a preset time.

Referring to FIG. 4, even after time t₃ when the application of the positive DC voltage to the baffle 130 ends, the DC power supply 350 may further apply a positive DC voltage to the baffle 130 for a preset time t′.

As a result, even after the application of the positive DC voltage to the baffle 130 ends, it is possible to separate a particle from the baffle 130 and effectively discharge the particle to the outside of a chamber.

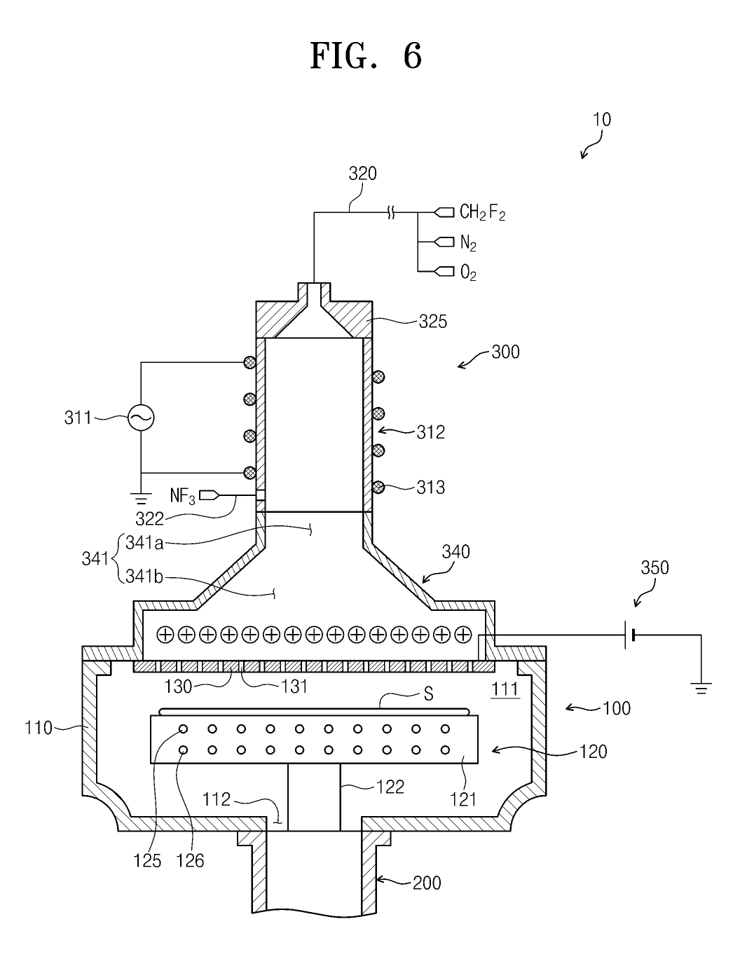

FIG. 6 is an exemplary diagram representing the behavior of a particle according to still another embodiment of the present invention.

As described with reference to FIG. 5, when a positive DC voltage is applied to the baffle 130 to attach particles generated during a process to the baffle 130, some particles may be positively-charged and attached still to the baffle 130 even if the positive DC voltage applied to the baffle 130 is interrupted.

According to the present embodiment, even after the application of the positive DC voltage to the baffle 130 ends, the DC power supply 350 applies a positive DC voltage to the baffle for a certain time once more and thus it is possible to effectively discharge particles attached to the baffle 130 to the outside of a chamber.

The embodiment in FIG. 4 applies a positive DC voltage to the baffle 130 once more after time t₃ when the application of the positive DC voltage ends, the number of times being applied may be two or more.

Furthermore, as described with reference to FIG. 1, the substrate processing device 10 may further include the intake duct 340 between the plasma chamber 312 and the process chamber 110 to connect a plasma generation space to a substrate processing space. In this case, the baffle 130 may be coupled to an end the intake duct 340 adjacent to the process chamber 110, such as a lower end of the intake duct.

As a result, since the distance between the baffle 130 and the plasma chamber 312 is secured to correspond to the size of the intake duct 340, a positive voltage applied to the baffle 130 may not affect plasma generation even if a positive DC voltage is applied to the baffle 130, as described previously.

Thus, since the operation of the DC power supply 350 for handing particles as described previously does not interfere with plasma generation, it is possible to prevent particle handing according to an embodiment of the present invention from decreasing the productivity of a process.

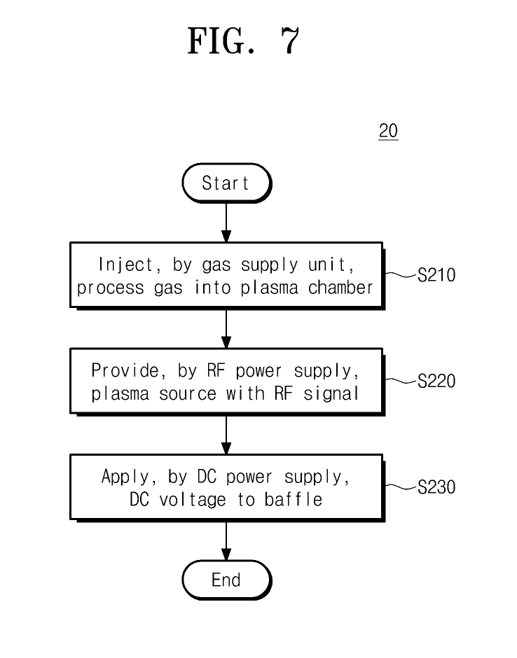

FIG. 7 is an exemplary flow chart of a method 20 of handing a particle according to an embodiment of the present invention.

The method 20 of handling the particle is performed by the substrate processing device 10 according to an embodiment of the present invention as described above to prevent the substrate S from becoming contaminated by the particle.

As shown in FIG. 7, the method 20 of handling the particle may include injecting by the gas supply unit 320 a process gas into the plasma chamber 312 in step S210, providing by the RF power supply 311 the plasma source 313 with an RF signal to process the substrate S in step S220, and applying by the DC power supply 350 a DC voltage to the baffle 130 to prevent the substrate S from becoming contaminated by the particle in step S230.

According to an embodiment of the present invention, applying the DC voltage in step S230 may include applying by the DC power supply 350 a negative DC voltage to the baffle 130. In this case, applying the negative DC voltage may include applying by the DC power supply 350 the negative DC voltage to the baffle 130 after substrate processing ends.

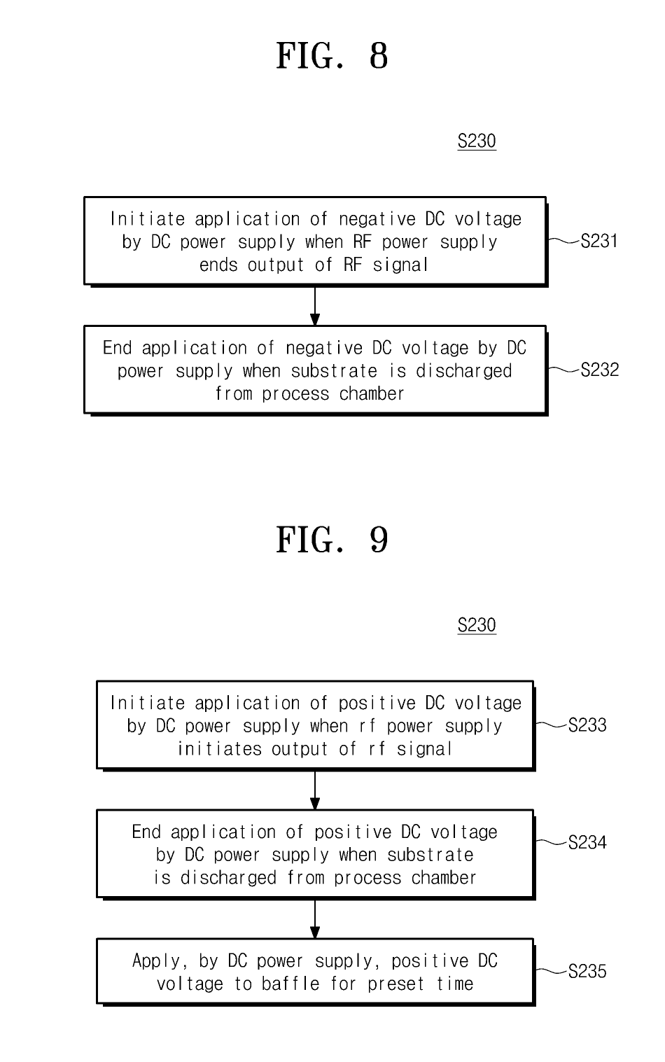

FIG. 8 is an exemplary flow chart of a DC voltage application process S230 according to an embodiment of the present invention.

As shown in FIG. 8, applying the negative DC voltage to the baffle 130 after substrate processing ends may include initiating the application of a negative DC voltage by the DC power supply 350 in step S231, when the RF power supply 311 ends the output of an RF signal.

Furthermore, applying the negative DC voltage to the baffle 130 after substrate processing ends may further include ending the application of the negative DC voltage by the DC power supply 350 in step S232, when the substrate S is discharged from the process chamber 110.

According to another embodiment of the present invention, applying the DC voltage in step S230 may include applying by the DC power supply 350 a positive DC voltage to the baffle 130. In this case, applying the positive DC voltage may include applying by the DC power supply 350 the positive DC voltage to the baffle 130 during substrate processing.

FIG. 9 is an exemplary flow chart of a DC voltage application process S230 according to another embodiment of the present invention.

As shown in FIG. 9, applying the positive DC voltage to the baffle 130 during the substrate processing may include initiating the application of a positive DC voltage by the DC power supply 350 in step S233, when the RF power supply 311 initiates the output of an RF signal.

Furthermore, applying the positive DC voltage to the baffle 130 during substrate processing may further include ending the application of the positive DC voltage by the DC power supply 350 in step S234, when the substrate S is discharged from the process chamber 110.

Also, according to still another embodiment of the present invention, the method 20 of handling the particle may further include applying by the DC power supply 350 a positive DC voltage to the baffle 130 for a preset time t′ in step S235, after the application of the positive DC voltage ends in step S234.

The method 20 of handing the particle according to an embodiment of the present invention as described previously may be produced as a program to be executed on a computer and may be stored in a computer readable recording medium. The computer readable recording medium includes all kinds of storage devices storing data that may be read by a computer system. Examples of the computer readable recording medium are a ROM, a RAM, a CD-ROM, a magnetic tape, a floppy disk, and an optical data storage device. According to an embodiment of the present invention, it is possible to prevent a particle from staying on a substrate, thus prevent the substrate from becoming contaminated, and improve the yield of a process.

According to an embodiment of the present invention, since handling a particle during a process does not interfere with plasma generation, it is possible to enhance the productivity of the process.

According to an embodiment of the present invention, it is possible to effectively discharge particles piled up in a chamber to the outside of the chamber.

Although the present invention is described above through embodiments, the embodiments above are only provided to describe the spirit of the present invention and not intended to limit the present invention. A person skilled in the art will understand that various modifications to the above-described embodiments may be made. The scope of the present invention is defined only by the following claims.

What is claimed is:

1. A substrate processing device comprising:
a process chamber providing a space in which a substrate is processed;
a substrate support unit arranged in the process chamber and supporting the substrate;
a plasma chamber providing a space in which plasma is generated;
a gas supply unit supplying a process gas to the plasma chamber;
a plasma source installed in the plasma chamber and generating the plasma from the process gas;
a radio frequency (RF) power supply providing the plasma source with an RF signal for generating the plasma;
a baffle arranged over the substrate support unit and evenly supplying the plasma to a processing space in the process chamber;
a direct current (DC) power supply applying a DC voltage to the baffle;
a discharge unit discharging a particle generated in the process chamber during substrate processing; and
a control unit controlling the DC power supply to prevent the contamination of the substrate by the particle and handing the particle.

2. The substrate processing device of claim 1, wherein the DC power supply supplies a negative DC voltage to the baffle.

3. The substrate processing device of claim 2, wherein the control unit enables the DC power supply to apply the negative DC voltage to the baffle after substrate processing ends.

4. The substrate processing device of claim 3, wherein the control unit enables the DC power supply to initiate the application of the negative DC voltage when the RF power supply ends the output of an RF signal.

5. The substrate processing device of claim 4, wherein the control unit enables the DC power supply to end the application of the negative DC voltage when the substrate is discharged from the process chamber.

6. The substrate processing device of claim 1, wherein the DC power supply applies a positive DC voltage to the baffle.

7. The substrate processing device of claim 6, wherein the control unit enables the DC power supply to apply the positive DC voltage to the baffle during substrate processing.

8. The substrate processing device of claim 7, wherein the control unit enables the DC power supply to initiate the application of the positive DC voltage when the RF power supply initiates the output of an RF signal.

9. The substrate processing device of claim 8, wherein the control unit enables the DC power supply to end the application of the positive DC voltage when the substrate is discharged from the process chamber.

10. The substrate processing device of claim 9, wherein the control unit enables the DC power supply to further apply a positive DC voltage to the baffle for a preset time after the application of the positive DC voltage ends.

11. The substrate processing device of claim 1, further comprising an intake duct arranged between the plasma chamber and the process chamber and connecting a plasma generation space to a substrate processing space,
wherein the baffle is coupled to an end of the intake duct adjacent to the process chamber.

12. A method of handling a particle generated during substrate processing in a substrate processing device, the method comprising:
injecting a process gas to a plasma chamber;
providing a plasma to a substrate; and
applying a DC voltage to a baffle to prevent the substrate from becoming contaminated by the particle.

13. The method of claim 12, wherein the applying of the DC voltage comprises applying a negative DC voltage to the baffle.

14. The method of claim 13, wherein the applying of the negative DC voltage comprises applying a negative DC voltage to the baffle after substrate processing ends.

15. The method of claim 14, wherein the applying of the negative DC voltage to the baffle after the substrate processing ends comprises initiating the application of a negative DC voltage when providing the plasma to the substrate ends.

16. The method of claim 15, wherein the applying of the negative DC voltage to the baffle comprises ending the application of a negative DC voltage when the substrate is discharged from a process chamber.

17. The method of claim 12, wherein the applying of the DC voltage comprises applying a positive DC voltage to the baffle.

18. The method of claim 17, wherein the applying of the positive DC voltage comprises applying a positive DC voltage to the baffle during substrate processing.

19. The method of claim 18, wherein the applying of the positive DC voltage to the baffle during the substrate processing comprises initiating the application of a positive DC voltage when initiating providing the plasma to the substrate.

20. The method of claim 19, wherein the applying of the positive DC voltage to the baffle during the substrate processing comprises ending the application of a positive DC voltage when the substrate is discharged from a process chamber.

21. The method of claim 20, further comprising, after the application of the positive DC voltage ends, applying by the DC power supply to apply a positive DC voltage to the baffle for a preset time.

22. A computer readable recording medium on which a program to execute the method of claim 12 is recorded.
